(19) United States
(12) Patent Application Publication
(10) Pub. No.: US 2024/0118723 A1
(43) Pub. Date: Apr. 11, 2024

(54) RECONFIGURABLE SMALL AREA BANDGAP WITH A NOVEL TECHNIQUE FOR SWITCHING BETWEEN ULTRA LOW POWER MODE AND HIGH ACCURACY MODE

(71) Applicant: Vidatronic, Inc., Austin, TX (US)

(72) Inventors: Hazem Hassan Mohamed Hammam, Cairo (EG); Sameh Ahmed Assem Ibrahim, Cairo (EG); Bishoy Milad Helmy Zaky, Cairo (EG); Moises E Robinson, Austin, TX (US)

(73) Assignee: Vidatronic, Inc., Austin, TX (US)

(21) Appl. No.: 17/956,809

(22) Filed: Sep. 29, 2022

(51) Int. Cl. G05F 3/26; G01R 35/00

(52) U.S. Cl. CPC G05F 3/267; G01R 35/007

(57) ABSTRACT

A bandgap apparatus includes an error amplifier; a bandgap core including 2 BJT devices and core resistors for proportional to absolute temperature (PTAT) and complementary to absolute temperature (CTAT) current generations; a reference resistor for reference voltage generation; an NMOS current mirror having NMOS devices; a PMOS current mirror having PMOS devices; and 4 switches for controlling operation in a high-power mode or a low-power mode, wherein the high-power mode consumes more power than the low-power mode, wherein the error amplifier is switched on and the NMOS current mirror is switched off in the high-power mode, or the error amplifier is switched off and the NMOS current mirror is switched on in the low-power mode.

### BACKGROUND

A fractional bandgap is a circuit that generates a poly reference current that is nearly constant with temperature and a constant reference voltage that doesn't change much with temperature and supply voltage variations. There are many families of bandgap reference (BGR) circuits, such as Brokaw BGR, sub-bandgap BGR, and all-MOSFET BGR. The main advantage of a fractional BGR is its ability to generate multiple values of reference voltages and reference currents with poly or constant behavior across temperatures. Other types either generate one constant value of 1.2V reference voltage or generate PTAT/CTAT reference current. The main challenge of BGR is accuracy, power, and area consumption tradeoff.

FIG. 1 shows a schematic block level diagram of a conventional fractional bandgap (100). The fractional bandgap (100) consists of a bandgap (BG) core (105), an error amplifier (110), current Mirrors (115), and a poly reference resistor (120). The BG core (105) mainly includes 3 resistors and 2 bipolar junction transistors (BJTs). One of the resistors (R₁, 125) has a complementary to absolute temperature (CTAT) current and the other two resistors (R_{2B}, 130) and (R_{2A}, 135) have proportional to absolute temperature (PTAT) currents through them, The 2 BJTs have a ratio of 1×(Q₂, 145) to 8×(Q₁, 140) or any ratio greater than 1:1. For example, the ratio can be 1:4, 1:8, 1:24, etc. based on the matching requirements. The core BJTs can be NPN or PNP based on the bandgap architecture. The error amplifier (110) sets its 2 inputs to have the same value, which is nearly equal to VEB of the BJT≈0.7V.

The current mirrors (115) mirror the overall summation of the PTAT and CTAT currents, generated through the BG core (105), to produce a poly current that is inversely proportional to the core resistor resistance. The current mirrors (115) are comprised of PMOS devices, among which M₁ (160) and M₂ (165) are the main core mirrors with the same size, while the device (M₃, 170) mirrors the same current flowing through M1 (160) and M2 (165) or a ratio thereof, depending on the mirror's size ratio, to generate a specific poly reference current (Ipoly) inversely proportional to the core resistor resistance (Rcore), wherein: Ipoly≈V/Rcore. Dumping this current in the poly resistor (R₃, 120) provides a constant voltage reference (V_{ref}, 180), which is independent of the resistor variation for the case of matching the poly resistor with the core resistor, where: V_{ref}≈V*Rpoly/Rcore. This architecture has the advantage of having a high accuracy due to the high loop gain. The main disadvantages of this technique are the high power and the large area consumption due to the high gain error amplifier with its biasing circuit.

FIG. 2 shows the generated 1.2V reference voltage (200), using the circuit of FIG. 1, across the MOSFET process corners; (FF_MOS, SS_MOS, FS_MOS, SF_MOS), the resistor corners; (FF_RES, SS_RES), temperature corners (−40° C. and 125° C.), and voltage supply (see FIG. 1, V_{DD}, 175) corners (2.5V and 4.5V). It shows that the maximum value (205) is 1.22V with +1.7% accuracy. The minimum value (210) is 1.177V which is −1.9%. Thus, the reference voltage inaccuracy is lower than ±2% across PVT corners.

FIG. 3 shows the quiescent power consumption (300) for the fractional bandgap circuit of FIG. 1 across same PVT corners. It is the quiescent current consumption through the bandgap ground multiplied by the power supply voltage. Typically, the quiescent power consumption is 35 μW (305) at 3.5V supply and 10 μA quiescent current (Iq). Across PVT, the maximum value (310) at 4.5V supply is 70 μW. The minimum value (315) at 2.5V supply is 17 μW.

FIG. 4 shows the schematic block level diagram of a low power opamp-less bandgap (400). The low power bandgap (400) consists of a BG core (405), an NMOS mirrors (490), a PMOS current Mirrors (415), and a poly reference resistor (420). The BG core mainly includes 3 resistors and 2 BJTs. One resistor (R₁, 425) has a CTAT current and the other two resistors (R_{2B}, 430) and (R_{2A}, 435) have PTAT currents flowing through them. The 2 BJTs have a ratio of 1×(Q₂, 445) to 8×(Q₁, 440) or any ratio greater than 1:1. The diode connected NMOS (M₅, 455) and its mirror (M₄, 450) have the same size with the same current flowing through them, which is equal to the overall summation of the PTAT and CTAT currents generated by the BG core (405), providing a poly current that is inversely proportional to the core resistor resistance in the BG core (405). In the PMOS current mirrors (415), PMOS devices (M₁, 460) and (M₂, 465) are the main core mirrors with the same size, while the PMOS device (M₃, 470) mirrors the same current flowing through (M₁, 460) and (M₂, 465) or a ratio thereof, depending on the mirror's size ratio, to generate a specific poly reference current (Ipoly) inversely proportional to the core resistor resistance, wherein:

$$Ipoly \approx \frac{V}{Rcore} .$$

This current flows through the poly resistor (R₃, 420) providing a constant voltage reference (V_{ref}, 480), which is independent of the resistor variation for the case of matching the poly resistor with the core resistor, wherein:

$$Vref = \frac{V * Rpoly}{Rcore} .$$

This architecture has the advantages of having low power and area consumption due to not having an error amplifier or its biasing circuit, which avoids their current and area consumption. The main disadvantage of this technique is the poor accuracy of the generated reference voltage and current because the mirroring is set by the NMOS mirrors, which is affected by their mismatch.

FIG. 5 shows the generated 1.2V bandgap reference voltage (500), using the opamp-less low power bandgap of FIG. 4, across the MOSFET process corners; (FF_MOS, SS_MOS, FS_MOS, SF_MOS), the resistor corners; (FF_RES, SS_RES), temperature corners (−40° C. and 125° C.), and voltage supply (see FIG. 4, V_{DD}, 475) corners (2.5V and 4.5V). It shows that the maximum value (505) is 1.25V with +4.2% accuracy. The minimum value (510) is 1.146V which is −4.5%. Thus, the reference voltage inaccuracy is in the range of ±5% across PVT corners.

FIG. 6 shows the quiescent power consumption (600) for the low power opamp-less bandgap circuit of FIG. 4 across same PVT corners. It is the quiescent current consumption through the bandgap ground multiplied by the power supply voltage. Typically, the quiescent power consumption is 7 μW (605) at 3.5V supply and 2 μA Iq. Across PVT, the maximum value (610) at 4.5V supply is 13 μW. The minimum value (615) at 2.5V supply is 5 μW.

While these prior art designs for fractional bandgaps each have certain advantages, they also have disadvantages. Therefore, there is still a need for better designs.

### SUMMARY

In one aspect, embodiments of the invention relate to a system architecture that includes one Bandgap circuit with 2 modes of operation. The bandgap circuit architecture can be any topology such as a traditional bandgap circuit or a fractional bandgap circuit. A bandgap circuit of the invention can generate poly current and voltage references with small variations across the process, supply, and temperature (PVT) corners. A bandgap of the invention shares a startup circuit, a BG core that includes 2 BJTs and PTAT/CTAT resistors, a PMOS current mirror (i.e., a current mirror with PMOS devices), and a poly reference resistor. In addition, bandgap circuit has an error amplifier and a NMOS current mirror (i.e., a current mirror with NMOS devices) for operating in the high-power and low-power modes, respectively. A set of switches are used to control the operations of the two modes. The circuit has one bit to control enabling the error amplifier and isolating the NMOS mirrors to work in the high-power, high-accuracy mode or disabling the error amplifier and connecting the NMOS mirrors to work in the low-power, low-accuracy mode. Having a BG core, a startup circuit, a poly reference resistor, and PMOS mirrors shared between the two modes reduces the power and the area consumption (as compared to the case of duplicating the startup, the BG core, the poly reference resistor, and the PMOS mirrors) by avoiding additional area and power for the case of designing two bandgaps with different accuracy and power specifications. Thus, sharing the sub-cells to achieve two modes with different specifications using switches saves power and area and improves the system efficiency.

In one aspect, an embodiment of the invention relates to a bandgap apparatus that comprises an error amplifier, a bandgap core comprising 2 bipolar junction transistors (BJTs) and core resistors, a poly resistor for reference voltage generation, an NMOS current mirror comprising 2 NMOS devices, a PMOS current mirror comprising PMOS devices, and 4 switches for controlling operation in a first mode (high-power mode) or a second mode (low-power mode), wherein the error amplifier is switched on and the NMOS current mirror is switched off in the first mode, or the error amplifier is switched off and the NMOS current mirror is switched on in the second mode.

In another aspect of the invention relates to a method for reference voltage generation using the bandgap apparatus of the invention. The method comprises the steps of: controlling the 4 switches to operate the bandgap apparatus in the first mode or the second mode, wherein the error amplifier is switched on and the NMOS current mirror is switched off in the first mode, or the error amplifier is switched off and the NMOS current mirror is switched on in the second mode; if the bandgap apparatus operates in the first mode, setting two inputs of the error amplifier to be the same across corners to generate a reference voltage with high-accuracy across corners; if the bandgap apparatus operates in the second mode, setting currents flowing through the 2 NMOS devices of the NMOS current mirror to be the same; generating a first current with the bandgap core, using the 2 BJTs and core resistors in the bandgap core to control the first current to be a PTAT current, a CTAT current, and providing a poly current to the PMOS current mirror; scaling the poly current flowing through the PMOS current mirror to be used as a poly reference current; and generating the reference voltage at the poly resistor using the poly reference current.

Other aspects of the invention will become apparent with the following description and the accompanying drawings.

### BRIEF DESCRIPTION OF DRAWINGS

The appended drawings illustrate several embodiments of the invention and are not to be considered limiting of its scope because the invention may admit to other equally effective embodiments.

FIG. 1 shows a block level circuit diagram of a prior art high-power high-accuracy fractional bandgap including a BG core with BJTs and resistors, an error amplifier, PMOS current mirrors, and a poly reference resistor.

FIG. 2 shows the high-power bandgap reference voltage value for the fractional bandgap of FIG. 1 across PVT corners to show the high output reference voltage accuracy of this architecture.

FIG. 3 shows the high-power bandgap quiescent power value for the fractional bandgap of FIG. 1 across PVT corners to show the high power consumption of this architecture.

FIG. 4 shows a block level circuit diagram of a prior art low-power, low-accuracy bandgap including a BG core with BJTs and resistors, NMOS mirrors, PMOS current mirrors, and a poly reference resistor.

FIG. 5 shows the low-power bandgap reference voltage value for the bandgap of FIG. 4 across PVT corners to show the lower output reference voltage accuracy of this architecture.

FIG. 6 shows a low-power bandgap quiescent power value for the bandgap of FIG. 4 across PVT corners to show the low power consumption for this architecture.

FIG. 7 shows a block level circuit diagram of a design of a bandgap with 2 different modes in accordance with one embodiment of the invention. The bandgap includes a BG core with BJTs and resistors, NMOS mirrors, an error amplifier, PMOS current mirrors, a poly reference resistor, and switches to control the operation to work in either a high-accuracy mode with high power consumption or a low-accuracy mode with low power consumption. Using one shared core, PMOS mirrors and poly reference resistor results in decreased power and the area consumption.

FIG. 8 shows a transient waveform of the high-power input pin. It starts with zero (low) to force the system to start in the low-power low-accuracy mode. Then, it goes to the supply voltage (high) to force the system to work in the high-power high-accuracy mode.

FIG. 9 shows a bandgap output reference voltage value across PVT corners to show the low output voltage accuracy at the beginning (low power mode) and the high output voltage accuracy when it works in the high-power mode.

FIG. 10 shows a bandgap quiescent power value across PVT corners to show the low power consumption at the beginning (low accuracy mode) and the high power consumption when it works in the high-accuracy mode.

FIG. 11 shows a circuit diagram of one embodiment of the invention applied to a traditional bandgap with 2 different modes. The circuit includes core BJTs and resistors, NMOS mirrors, an error amplifier, PMOS current mirrors, a reference resistor, and switches to control the operation to work in either the high accuracy mode with high power consumption or the low accuracy mode with low power consumption. Using one shared core, one group of PMOS mirrors, and one reference resistor results in decreased power and the area consumption.

### DETAILED DESCRIPTION

Aspects of the present disclosure are shown in the above-identified drawings and are described below. In the description, like or identical reference numerals are used to identify common or similar elements. The drawings are not necessarily to scale and certain features may be shown exaggerated in scale or in schematic in the interest of clarity and conciseness.

Most systems containing a bandgap require an accurate reference voltage and accurate bias current for other blocks; however, these systems may also require low power consumption in some modes, such as powering-up or sleep modes. Conventionally, such systems may require two bandgaps for different modes: a high-accuracy bandgap for accurate current and voltage generation for the normal high-power operation and a low-power bandgap with lower accuracy for the powering-up or sleep modes. Embodiments of the invention relate to system architectures that include one bandgap circuit with 2 modes of operation—i.e., a high-power, high-accuracy mode and a low-power, low-accuracy mode.

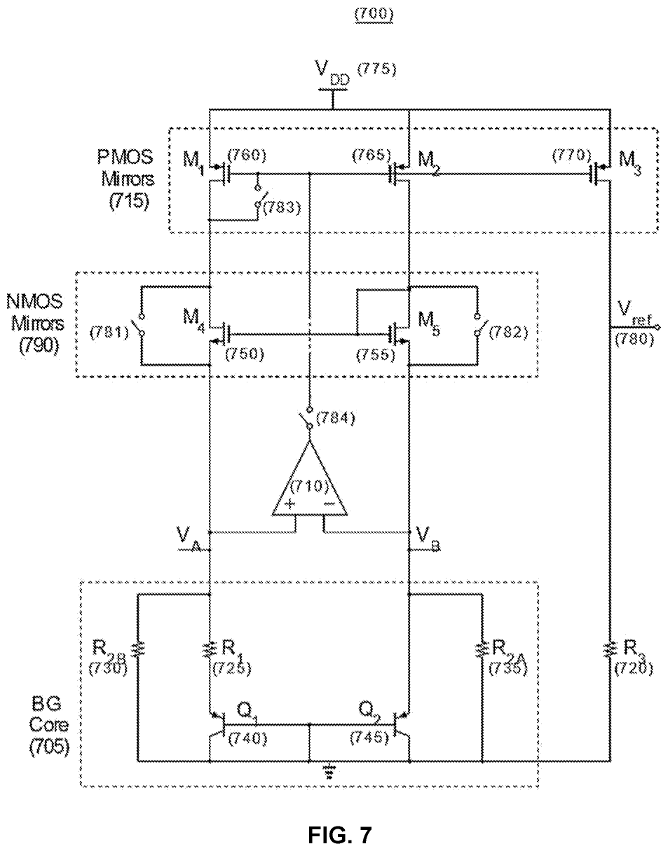

FIG. 7 shows a simplified block level circuit diagram of a dual-mode bandgap (700) in accordance with one embodiment of the invention. The dual-mode bandgap (700) comprises one shared BG core (705), an error amplifier to work in the high-power mode (710), NMOS current mirrors (790) to work in the low-power mode, shared PMOS mirrors (715) for reference current mirroring, 4 MOS switches (784), (781), (782), and (783) for switching between different modes, and one shared poly reference resistor (R₃, 720) for reference voltage (V_{ref}, 780) generation in the two modes.

The error amplifier (710) is a high-gain amplifier, which may be a 5T-OTA (operational transconductance amplifier), a 2-stage error amplifier, a folded cascade error amplifier, or any other topology that guarantees a high loop gain specification.

The BG core (705) mainly includes 3 resistors and 2 bipolar junction transistors (BJTs). One of the resistors (R₁, 725) has a CTAT current and the other two resistors (R_{2B}, 730) and (R_{2A}, 735) have PTAT currents flowing through them. The core BJTs can be NPN or PNP based on the bandgap architecture. The 2 BJTs have a gain ratio of 1×(Q₂, 745) to 8×(Q₁, 740) or any ratio greater than 1:1, such as 1:4, 1:8, 1:24, etc., based on the matching requirements. The BG core resistors and the reference resistor can be any resistor type, such as poly resistors or metal resistors or any other type. In preferred embodiments, the resistors are the types having lower temperature coefficients such that they have better current and voltage accuracy across temperatures.

The switches (781, 782, 783, and 784) control the operation and the working modes by having either the high-power mode switches ON and the low-power mode switches OFF or the high-power mode switches OFF and the low-power mode switches ON. Using these switches allows the bandgap to operate in two modes without requiring duplicate core circuit, startup circuit, mirrors, or poly resistor. The switches may be any suitable transistor switches, such as bipolar junction transistor switches or MOS (e.g., MOSFET) transistor switches.

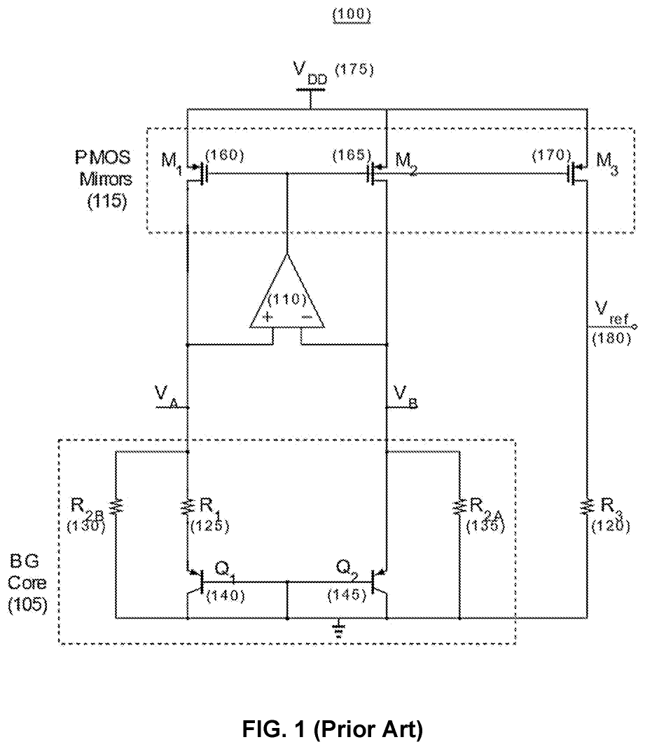

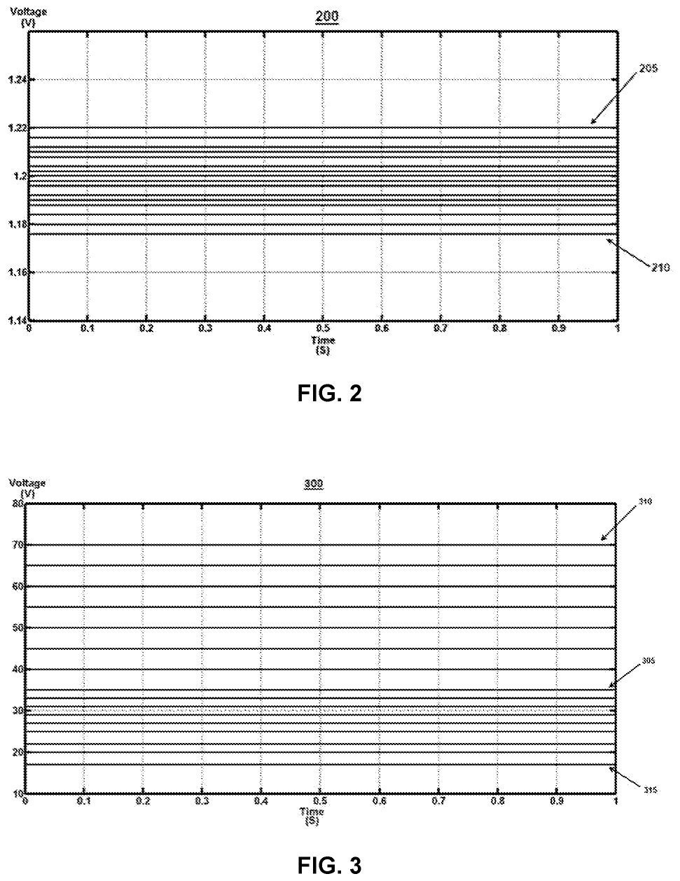

In the high-power, high-accuracy mode, the switches (784), (781), (782) are short circuit (ON), while the switch (783) is open circuit (OFF). This connects the error amplifier (710) output to the PMOS mirrors (715) gate and shorts the NMOS mirrors (790) to bypass them and to neglect their effects. This high-power, high-accuracy mode provides the same architecture and operation as those of the high-power, high-accuracy bandgap (100) shown in FIG. 1. In this high-power, high-accuracy mode, the error amplifier (710) sets its 2 inputs to have the same value, which is nearly equal to VEB of the BJT≈0.7V. The PMOS current mirrors (715) mirror the overall summation of the PTAT and CTAT generated currents, providing a poly current generated through the BG core (705), wherein the poly current is inversely proportional to the core resistor resistance. The PMOS devices (M₁, 760) and (M₂, 765) are the main core mirrors with the same size, while the PMOS device (M₃, 770) mirrors the same current flowing through PMOS devices (M₁, 760) and (M₂, 765) or a ratio thereof, depending on the mirror's size ratio, to generate a specific poly reference current (Ipoly) that is inversely proportional to the core resistor resistance, wherein:

$$Ipoly \approx \frac{V}{Rcore} .$$

Dumping this current in the poly resistor (R₃, 720) provides a constant voltage reference (V_{ref}, 780) which is independent of the resistor variation when the poly resistor matches the core resistor, where:

$$Vref = \frac{V * Rpoly}{Rcore} .$$

This architecture has the advantage of having high accuracy due to the high loop gain of the error amplifier loop. The main disadvantage is the high power consumption due to the need for the error amplifier and its biasing circuit.

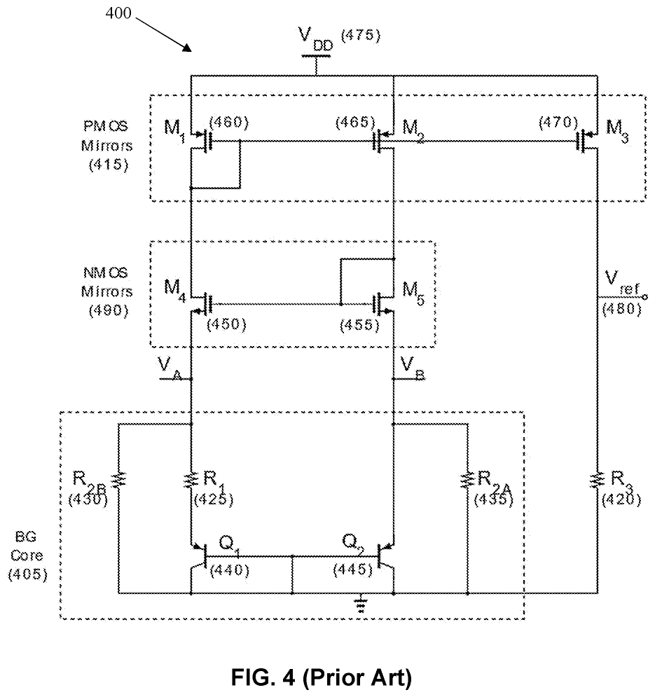

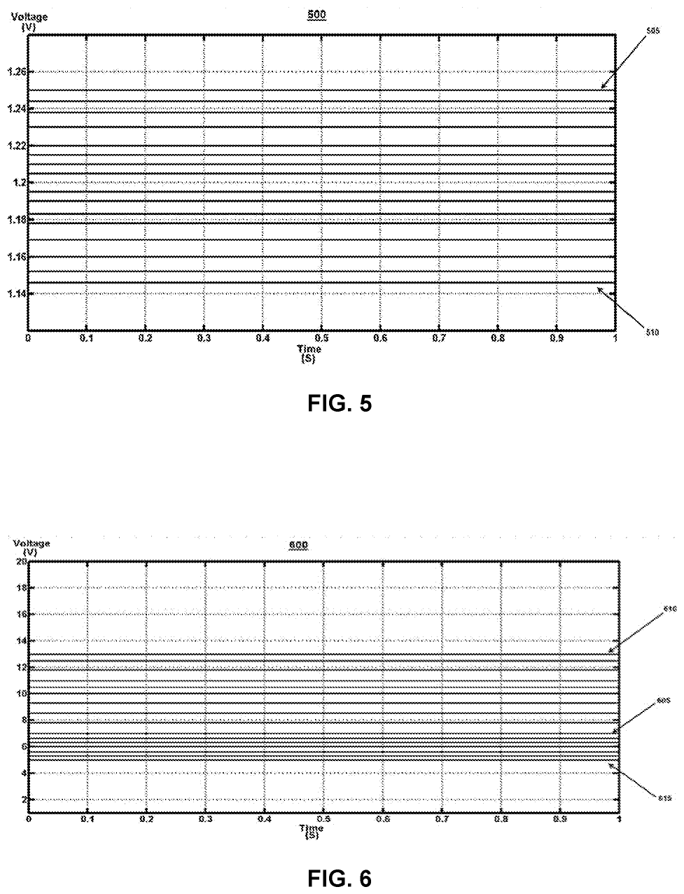

In the low-power, low-accuracy mode, the switches (784), (781), (782) are open circuit (OFF), while the switch (783) is short circuit (ON). This low-power, low-accuracy mode isolates the error amplifier (710) output from the PMOS mirrors (715) gate and connects the NMOS mirrors (790) and the gate-drain connection of the device (M₁, 760) to be the main PMOS diode connected mirror. This provides the same architecture and operation as those of the low-power low-accuracy bandgap (400) shown in FIG. 4. In this low-power, low-accuracy mode, the diode connected NMOS (M₅, 755) and its mirror (M₄, 750) have the same size with the same current flowing through them; this current is equal to the overall summation of the PTAT and CTAT core generated currents and provides a poly current that is inversely proportional to the core resistor resistance. The PMOS devices (M₁, 760) and (M₂, 765) are the main core mirrors with the same size. The other PMOS device (M₃, 770) mirrors the same current flowing through PMOS devices (M₁, 760) and (M₂, 765) or a ratio thereof, depending on the mirror's size ratio, to generate a specific poly reference current that is inversely proportional to the core resistor resistance, where:

$$Ipoly \approx \frac{V}{Rcore} .$$

This current flows through the poly resistor (R₃, 720) providing a constant voltage reference (V_{ref}, 780) that is independent of the resistor variation in case of matching the poly resistor with the core resistor, where:

$$Vref = \frac{V * Rpoly}{Rcore} .$$

This architecture has the advantages of having low power consumption due to turning off both the error amplifier and its biasing circuit, which avoids their current consumption. The main disadvantage of this technique is the poor accuracy of the generated reference voltage and current because the mirroring is set by the NMOS mirrors, which are affected by their mismatch.

The main advantages of the novel techniques of the invention include having two different bandgap circuits with different power/accuracy requirements using only one shared core resistors, one core BJTs, one group of PMOS mirrors, and one shared poly reference resistance, and using adaptive switches to enable either the high-power high-accuracy bandgap or the low-power low-accuracy bandgap. Having most of the sub-blocks shared between the two operation modes significantly decreases the power and the area consumption (by 50% of these cells consumption), as compared to using two bandgaps for the two modes with two startup, core, mirrors, and poly resistor cells.

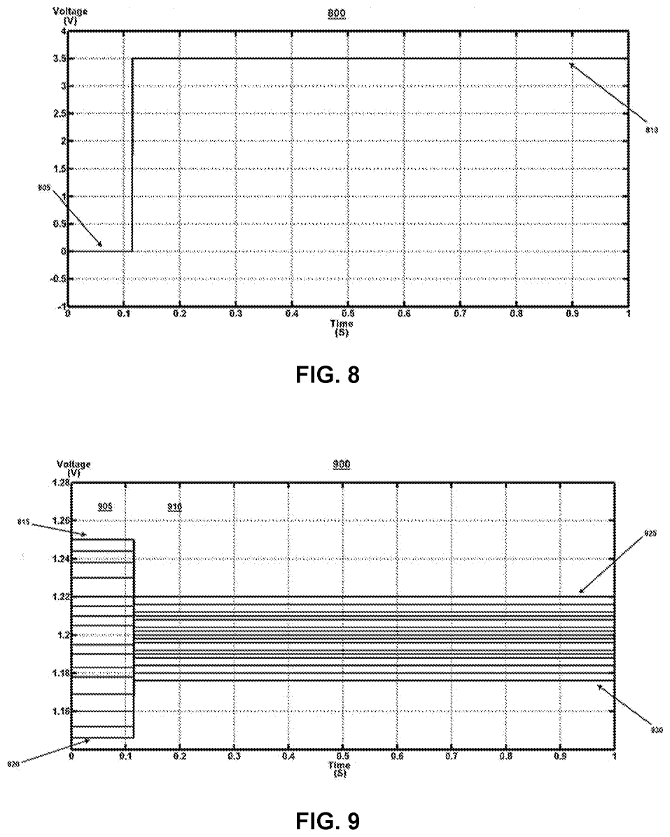

FIG. 8 shows a transient waveform of a high-power input pin signal (800) that controls the operating bandgap mode (high power or low power mode) for the fractional bandgap circuit of FIG. 7. The signal starts with zero (low) to force the high-power mode switches to be OFF and the low-power mode switches to be ON to start the system in the low-power low-accuracy mode (805). Then, the signal goes to the supply voltage (high) to force the high-power mode switches to be ON and the low-power mode switches to be OFF to force the system to switch to the high-power high-accuracy mode (810).

FIG. 9 shows the generated 1.2V bandgap reference voltages (900) for the fractional bandgap circuit of FIG. 7 across the MOSFET process corners; (FF_MOS, SS_MOS, FS_MOS, SF_MOS), the resistor corners; (FF_RES, SS_RES), temperature corners (−40° C. and 125° C.), and voltage supply (475) corners (2.5V and 4.5V). Initially, the low-power mode is enabled (905) which shows that the maximum reference value (915) is 1.25V with +4.2% accuracy. The minimum value (920) is 1.146V which is −4.5%. Thus, the reference voltage inaccuracy is in the range of ±5% across PVT corners for the low power-mode. After switching to the high-power mode (910), it shows that the maximum reference value (925) is 1.22V with +1.7% accuracy. The minimum value (930) is 1.177V which is −1.9%. Thus, the reference voltage inaccuracy is lower than ±2% across PVT corners in the high-power mode.

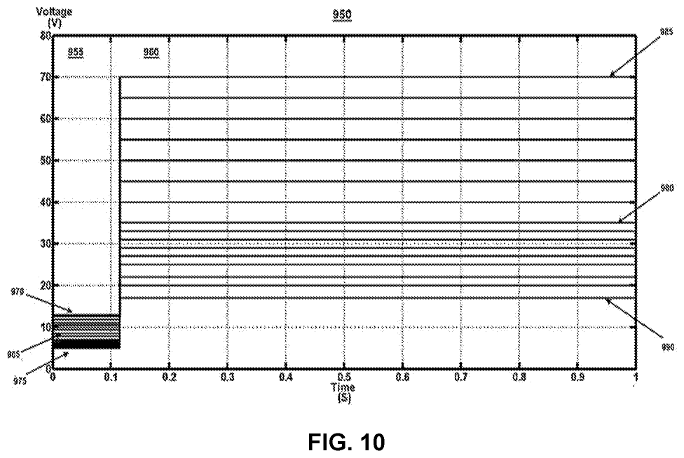

FIG. 10 shows the quiescent power consumption (950) for the fractional bandgap circuit of FIG. 7 across same PVT corners. It is the quiescent current consumption through the bandgap ground multiplied by the power supply voltage. Initially, the low-power mode is enabled (955). Typically, the quiescent power consumption is 7 μW (965) at 3.5V supply and 2 μA Iq. Across PVT, the maximum value (970) at 4.5V supply is 13 μW. The minimum value (975) at 2.5V supply is 5 μW. After switching to the high-power mode (960), typically, the quiescent power consumption is 35 μW (980) at 3.5V supply and 10 μA Iq. Across PVT, the maximum value (985) at 4.5V supply is 70 μW. The minimum value (990) at 2.5V supply is 17 μW.

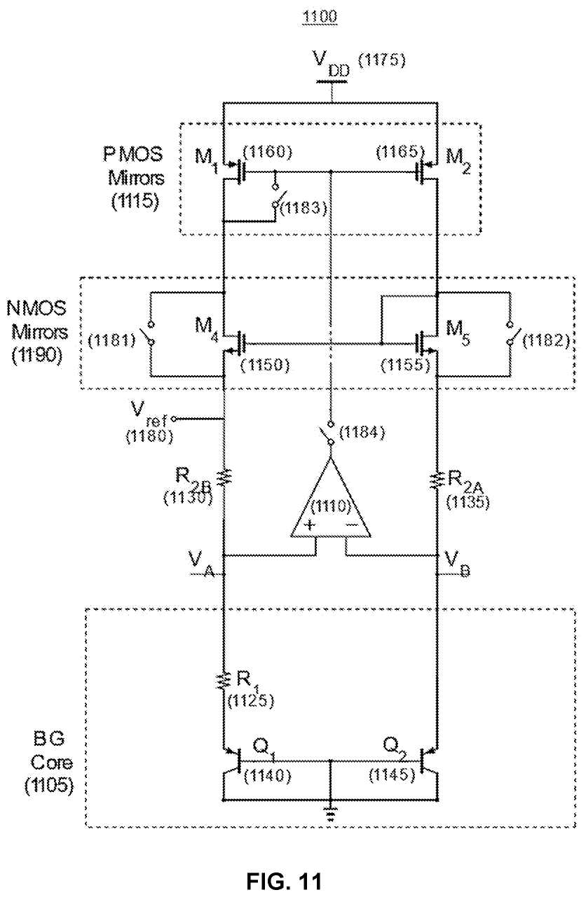

While the example of FIG. 7 shows a fractional bandgap topology, embodiments of the invention can also be applied to traditional bandgap topology. FIG. 11 shows a block level circuit diagram of a traditional dual mode bandgap (1100) in accordance with one embodiment of the invention. The dual-mode design has a traditional bandgap topology and comprises a shared BG core (1105), an error amplifier (1110) to work in the high-power mode, NMOS current Mirrors (1190) to work in the low-power mode, shared PMOS mirrors (1115) for reference current mirroring, 4 switches (1184), (1181), (1182), and (1183) for switching between different modes, and one shared reference resistor (1130) for reference voltage (V_{ref}, 1180) generation in the two modes. The switches may be any suitable transistor switches, such as bipolar transistor switches or MOS (e.g., MOSEFT) transistor switches.

The switches control the operation and the working modes by having either the high-power mode switches ON and the low-power mode switches OFF or the high-power mode switches OFF and the low-power mode switches ON, without requiring additional core circuit, startup circuit, mirrors or reference resistor. In the high-power high-accuracy mode, the switches (1184), (1181), (1182) are short circuit (ON) while the switch (1183) is open circuit (OFF). This connects the error amplifier (1110) output to the PMOS mirrors (1115) gate and shorts the NMOS mirrors (1190) to neglect their effect. This provides the same architecture and operation of a high-accuracy traditional bandgap with an error amplifier.

In the low-power low-accuracy mode, the switches (1184), (1181), (1182) are open circuit (OFF) while the switch (1183) is short circuit (ON). This isolates the error amplifier output from the PMOS mirrors (1115) gate and connects the NMOS mirrors (1190) and the gate-drain connection of the device (1160) to be the main PMOS diode connected mirror. This decreases the power consumed in the error amplifier and its biasing circuit and generates the current through the reference resistor through the NMOS mirrors (1190) to generate the reference voltage Vref (1180). The accuracy is lower in this mode as the current mirroring is affected by the mismatch between the NMOS mirrors and the PMOS mirrors.

Advantages of embodiments of the invention include having two different bandgap circuits with different power/accuracy requirements using only one shared core resistors, one core BJTs, one group of PMOS mirrors, and one shared reference resistance Using adaptive switches to control enabling either the high-accuracy or the low-power bandgap. Having most of the sub-blocks shared decreases the power and the area consumption much (by 50% of these cells consumption) compared to using two bandgaps for the two modes with two startup, core, mirrors, and poly resistor cells. This is applied to the fractional bandgap (700) and the traditional bandgap (1100) and can be applicable to other topologies.

Embodiments of the invention have been illustrated with specific examples. One skilled in the art would appreciate that these examples are for illustration and are not intended to limit the scope of the invention because other modifications and variations are possible without departing from the scope of the invention. Therefore, the scope of protection should be limited only by the attached claims.

What is claimed is:

1. A bandgap apparatus, comprising:
an error amplifier;
a bandgap core comprising 2 bipolar junction transistors (BJTs) and core resistors for PTAT and CTAT current generations;
a poly resistor for reference voltage generation;
an NMOS current mirror comprising 2 NMOS devices;
a PMOS current mirror comprising PMOS devices; and
4 switches for controlling operation in a first mode or a second mode, wherein the first mode consumes more power than the second mode,
wherein the error amplifier is switched on and the NMOS current mirror is switched off in the first mode, or the error amplifier is switched off and the NMOS current mirror is switched on in the second mode.

2. The bandgap apparatus of claim 1, wherein the bandgap apparatus has a traditional bandgap topology.

3. The bandgap apparatus of claim 1, wherein the bandgap apparatus has a fractional bandgap topology.

4. The bandgap apparatus of claim 1, wherein the error amplifier is a 5T-OTA, a 2-stage error amplifier, or a folded cascade error amplifier.

5. The bandgap apparatus of claim 1, wherein the one or more core resistors or the reference resistor comprises a poly resistor or a metal resistor.

6. The apparatus of claim 1, wherein the 2 BJTs in the bandgap core are NPN or PNP.

7. The apparatus of claim 1, wherein the 2 BJTs in the bandgap core have a gain ratio of 1:4, 1:8, or 1:24.

8. A method for reference voltage generation using the bandgap apparatus of claim 1, comprising:
controlling the 4 switches to operate the bandgap apparatus in the first mode or the second mode, wherein the error amplifier is switched on and the NMOS current mirror is switched off in the first mode, or the error amplifier is switched off and the NMOS current mirror is switched on in the second mode;
if the bandgap apparatus operates in the first mode, setting two inputs of the error amplifier to be the same across corners to generate a reference voltage with high accuracy across corners;
if the bandgap apparatus operates in the second mode, setting currents flowing through the 2 NMOS devices of the NMOS current mirror to be the same;
generating a current with the bandgap core, using the 2 BJTs and core resistors in the bandgap core to control the poly current through the PMOS current mirror;
scaling the poly current flowing through the PMOS current mirror to be used as a poly reference current; and
generating the reference voltage at the poly resistor using the mirrored poly reference current.
